(19) United States
(12) Patent Application Publication
(10) Pub. No.: US 2006/0250143 A1
(43) Pub. Date: Nov. 9, 2006

(54) Capacitive sensor and associated methods of operation

(76) Inventors: Anthony Moon, Cardiff (GB); Ceri Clatworthy, Swansea (GB); Karim Tshibangu, London (GB)

Correspondence Address: DICKSTEIN SHAPIRO LLP, 1825 EYE STREET NW, Washington, DC, 20006-5403, US

(21) Appl. No.: 10/537,862

(22) PCT Filed: Dec. 8, 2003
(86) PCT No.: PCT/GB03/05350

§ 371 Date: Jun. 21, 2006

(30) Foreign Application Priority Data
Dec. 6, 2002 (GB) 0228562.5

(51) Int. Cl. G01R 27/26; H03K 17/955

(52) U.S. Cl. 324/674; 340/562

(57) ABSTRACT

A method of detecting a proximate object using a capacitive sensor system, being measuring output signal data from the sensor over predetermined distance intervals and comparing the output signal data with predetermined comparison data indicative of an ideal sensor output signal sequence. Based on the comparison moderated data is output, such that, where an obtained output signal data value is lower value than a corresponding comparison data value, the moderated output data is given the value of the comparison data value, and otherwise the moderated output signal data is given the value of the obtained output signal data. Therefore the detection of low objects is improved through a comparison with data indicative of an ideal response signal.

The present invention relates to a capacitive sensor and method of operation of such a sensor particularly for attachment to a vehicle for use in detecting the proximity of objects, for example to assist when manoeuvring a vehicle, and as a collision avoidance device in a vehicle.

Capacitive proximity sensors are commonly used in industrial applications for locating the presence of materials and performing end-stop location. Of late capacitive sensors have been used for aircraft measurement to the ground at least since the 1940's. Of late, capacitive sensors have been used in parts of cars for collision avoidance purposes, and in recent years a number of luxury cars have been fitted with sensors particularly on the rear of the vehicle to warn the driver of objects. In operation when the vehicle is being reversed, a collision with unseen or obscured objects can be avoided whilst still being able to position the vehicle close to such objects, e.g. walls, bollards etc.

Capacitive sensors have guard and sensor plates which are connected to a control unit. In use, the control unit supplies high frequency signals to the sensing and guard plates. Objects in the vicinity of the vehicle present a capacitance to ground. In fact this capacitance is formed by two capacitances in series, namely a capacitance between the sensor plate and the object in series with a capacitance between the object and ground. This latter capacitance is actually formed by the capacitance between the object and the surface on which the object and the vehicle are positioned in series with the capacitance between that surface and the electrical ground of the vehicle. However, this latter capacitance is very large compared to the other capacitances and so it can be considered as a direct connection between the surface and electrical ground in the vehicle sensor. The control unit measures this capacitance between the sensor plate and ground. The unit may be triggered automatically when reverse gear is engaged (for a rear mounted system), manually or otherwise.

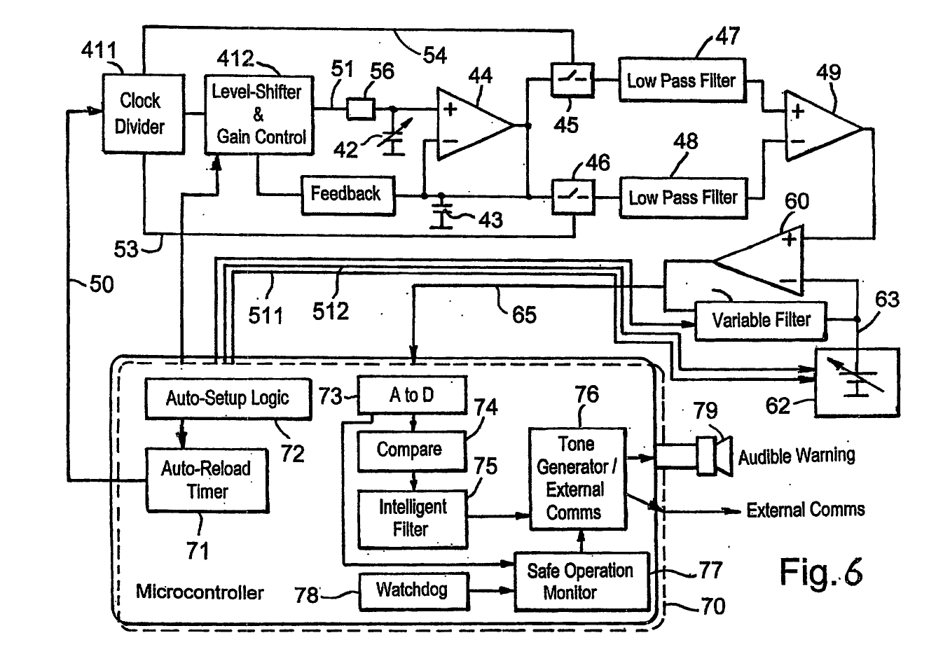

UK Patent Application No. 0109269.1 discloses a control and detector circuit for a capacitive sensor. An example of a circuit controlled using a micro-controller, which is disclosed in this patent application, is illustrated in FIG. 6. A clock unit 411, 412 in the detector circuit generates a square wave AC signal 51 which is fed to the sensor plate through a high value series resistor 56. The capacitance between the sensor plate and ground acts as a series capacitor 42. This capacitor 42 forms an RC circuit with the resistor 56. Consequently, the voltage between sensor plate and ground is an integrated square wave. This integrated square wave is essentially rectified and its amplitude is measured. If the vehicle is reversed towards an obstruction, the capacitance between the sensor plate and ground increases. This has the effect of causing the amplitude of the AC signal across the capacitor 42 to decrease. This change in capacitance is measured to provide an indication of the distance from any objects to the sensor and hence the vehicle.

The voltage on the sensor plate is fed to an amplifier 44, which then passes the signal to a synchronous rectifier 45,46,47,48,49 to reduce the sensitivity to noise and interfering signals. The signal produced provides an indication of the capacitance of the sensor plate to ground, which is an indication of any objects close to the sensor plate, and hence the rear of the vehicle.

In use, as an obstruction is approached, the input voltage 65 to the micro-controller 70 increases. This voltage is converted to a digital signal in an A to D converter 73 and its amplitude compared 73 to reference levels to determine how close the sensor is likely to be to an object. The device then provides 75,76 an audible signal through a speaker or sounder 79 or the like.

This audible signal can be provided in any number of ways. For example the control unit can be arranged to provide different tones depending on the range to an obstruction. A broken tone could be output when the object is considered to be 80 cm away, for example, then as the obstruction moves closer, at about 50 cm the tone could become faster, and finally at a close range of about 30 cm the tone could change to a continuous tone to signal the driver to stop reversing. These are called PAR, MID and NEAR warnings and are triggered by the amplitude of the sensor output. When the output rises above a preset threshold, the appropriate warning is generated.

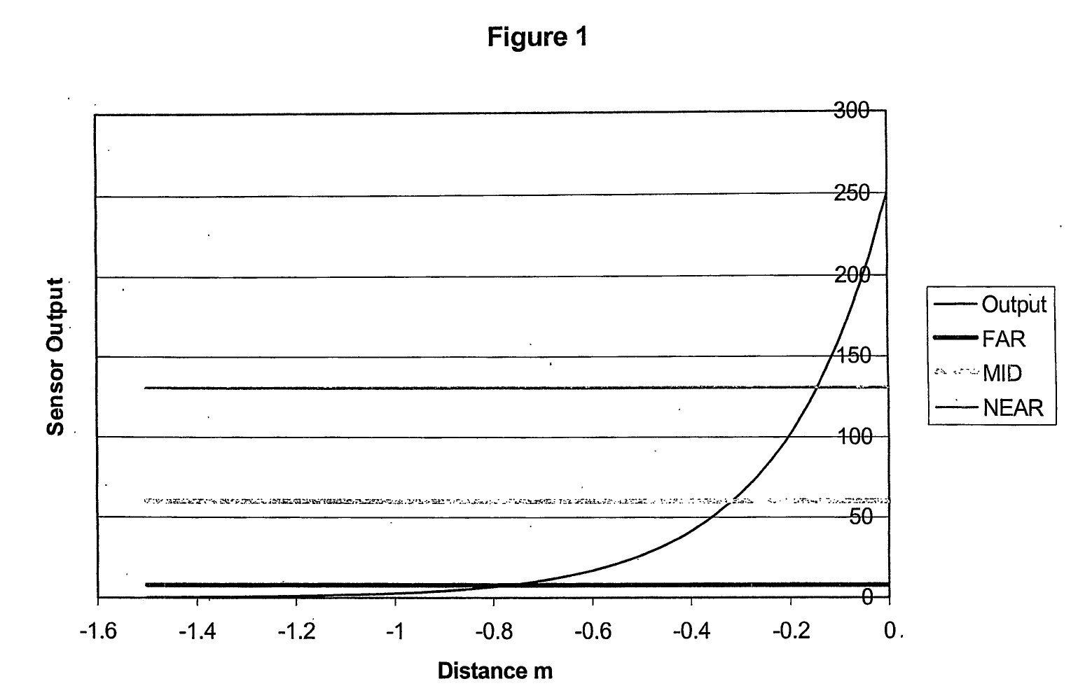

With reference to FIG. 1 a typical exponential capacitive sensor output is illustrated and an example of possible ranges for the warnings. The sensor output is given numerically in the graph, such that an amplitude of 255 units is equivalent to a 5V change in sensor output after amplification. For low sensor outputs with an amplitude between about 10 and 60, corresponding to an object distance of between about 0.3 and 0.75 metres, a FAR warning would be generated. For output signals with an amplitude between about 60 and 130, corresponding to an object distance of between about 0.15 and 0.3 metres, a MD warning would be generated. For output signals with an amplitude above 130, a NEAR warning would be generated.

However, different materials have different effects on the output of a capacitive sensor. For example people, concrete, wood, metal, stone and plants provide a strong output from the sensor whereas other objects can give weaker responses, in particular low mass insulating objects such as plastics. This may be problematic in view of the likelihood of encountering plastic objects such as cones when manoeuvring a vehicle. Therefore, although an object may be close to the vehicle, the signal response picked up by the sensor may be weak, so that the sensor gets an incorrect indication of the proximity of the object, effectively making it appear further away than it is.

There is therefore a need for an improved capacitive sensor, particularly one with improved sensitivity towards objects with a weak output response.

A further problem, particularly associated with objects with a weak output response is that it is often difficult to extract the output signal associated with an object from a data stream in view of noise.

There is therefore also a need for a capacitive sensor with improved noise detection and suppression.

Capacitive sensors are generally located behind the bumper bar or fender of a vehicle and are positioned as high as possible. This minimises the noise in the output caused-by small changes in the height of the vehicle above ground as it moves. A typical sensor would be mounted behind the bumper skin about 60 cm above the ground (e.g. Ford Focus). However, in view of this elevation, existing sensor systems are generally not sensitive to the existence of low objects, and a vehicle can hit them before a NEAR warning is sounded. A low object is any object below the height of the sensor and covers objects such as kerbs and low stakes in the ground.

There is therefore also a need for a sensor with improved sensitivity in regard to the detection of low objects, being objects below the height of the sensor.

An additional problem exists in relation to the initial capacitance reference provided to the control unit when the system is activated. With reference to FIG. 6, a micro-controller 70 is typically provided to control the various elements of the detector circuit and to process the output to provide indications to the user. To provide a device that is sufficiently sensitive, it is necessary to measure small changes in capacitance (<1 pF). Consequently, the changes in amplitude of the measured AC signal are small. When the device is first enabled, the micro-controller 70 therefore adjusts both the frequency and amplitude of the AC signal and also a DC component so that the output from the detector is within a defined range. Typically, the sensor starts with conditions appropriate to a dry bumper with no objects within range (i.e. minimum capacitance). This requires a moderate amplitude and relatively high frequency.

The clock divider 411 is set to the chosen start frequency and the level shifter and gain control 412 are set to minimum gain. The micro-controller 70 measures the output 65 from the DC amplifier 60 via its A to D converter 73 after waiting a suitable settling time. If the measured voltage 65 is too high (close to +5V) it reduces the frequency. This is continued until either the voltage falls to near 0V or it reaches a threshold frequency that is pre-defined in the software.

If the output voltage 65 falls to near 0V, typically <1.5V, it means that the approximate set-up conditions for the prevailing environment have been found. The micro-controller 70 provides fixed discrete frequencies 50, generated by varying the divide ratio of the system clock. These may be too far apart for optimal tuning, so a second stage of tuning is provided. A variable voltage source 62 produces a DC voltage under the control of the micro-controller 70. This voltage is subtracted from the differential amplifier 49 output by a second differential amplifier 60. The voltage produced by the voltage source 62 is increased or decreased until the input voltage 65 to the micro-controller 70 falls close to zero (typically <0.3V). The sensor is then set up correctly to sense small increases in capacitance as the vehicle is moved towards an obstruction.

However, the sensor electronics and output can drift slowly with time, temperature etc, which results in less accuracy. Further, the accuracy of the initial reference can be undermined by changes in the height of the sensor when the vehicle is moving, which may be caused due to slopes and bumps in the road and the effect of acceleration/deceleration on the suspension.

There is therefore a further need for a capacitive sensor with improved accuracy and increased range.

There is also a need for an improved method of operating a capacitive sensor.

It is an object of this invention to overcome or alleviate at least one problem of the prior art.

According to one aspect, the present invention provides a method for moderating an output from a capacitive sensor system comprising:

measuring the output from the capacitive sensor at spaced apart intervals;

comparing a measured output value with a corresponding comparison data value indicative of an ideal sensor output to determine if the measured output value differs from the comparison data value; and

determining a moderated output value, such that the moderated output value corresponds to the measured output value except where the comparison shows the measured output value to differ from the corresponding comparison data value, wherein the moderated output value is adjusted to reduce the difference from the comparison data value.

This aspect of the present invention is able to improve the detection of low objects through a comparison with data indicative of an ideal response signal.

According to another aspect, the present invention provides a method for detecting an object using a capacitive sensor output signal, comprising:

(a) measuring an output from the capacitive sensor at spaced apart intervals to obtain a sequence of output values;

(b) comparing the sequence of sensor output values with predetermined comparison data indicative of an ideal sensor output sequence; and

(c) determining that an object has been detected where a match is obtained between the sequence of output values and the comparison data

This aspect of the invention allows a weaker signal response indicative of the existence of a proximate object to be extracted from a noisy data stream.

Sensor devices and other associated apparatus incorporating the principles of these aspects of the invention are also provided.

According to a still further aspect of the present invention, there is provided a method of regulating a controller in a capacitive sensor system, the controller having a controller reference, the method comprising:

measuring output values from the capacitive sensor at spaced apart intervals;

periodically determining whether a comparison value, indicative of the measured output, differs from the controller reference; and

determining whether to update the controller reference based upon the difference between the comparison value and the measured output.

This further aspect of the invention allows the micro-controller's reference to be dynamically updated to accurately reflect the operating conditions of the sensor.

Preferably this aspect of the invention further comprises determining whether the system is in motion; and

(i) where the system is not in motion and the comparison value differs from the controller reference, the controller reference is updated so as reduce the difference between the comparison value and the controller reference; or

(ii) where the system is in motion:

comparing the difference between the comparison value and the controller reference with a threshold value; and

where the difference is smaller than the threshold value, updating the controller reference so as to reduce the difference between the comparison value and the controller reference.

These aspects of the invention can also be applied to any system in which there is a known relationship between the output and distance from a target or obstruction.

There will now be described specific embodiments of the present invention with reference to the accompanying drawings in which:

FIG. 1 illustrates graphically illustrates a typical exponential sensor output showing possible ranges for different warnings signals;

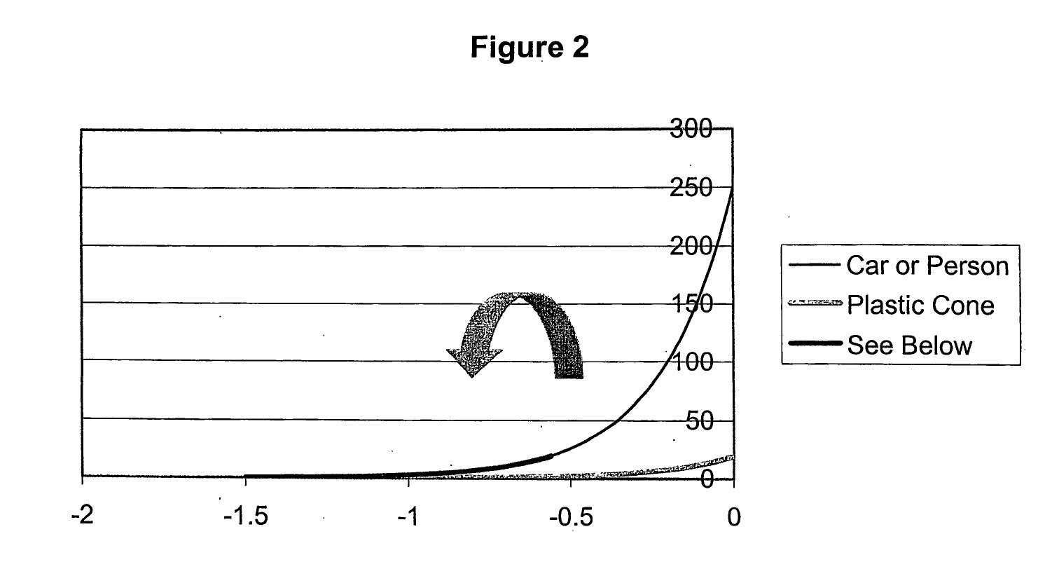

FIG. 2 graphically compares a typical sensor output for an object such as a car or person compared with a typical sensor output for a plastic cone;

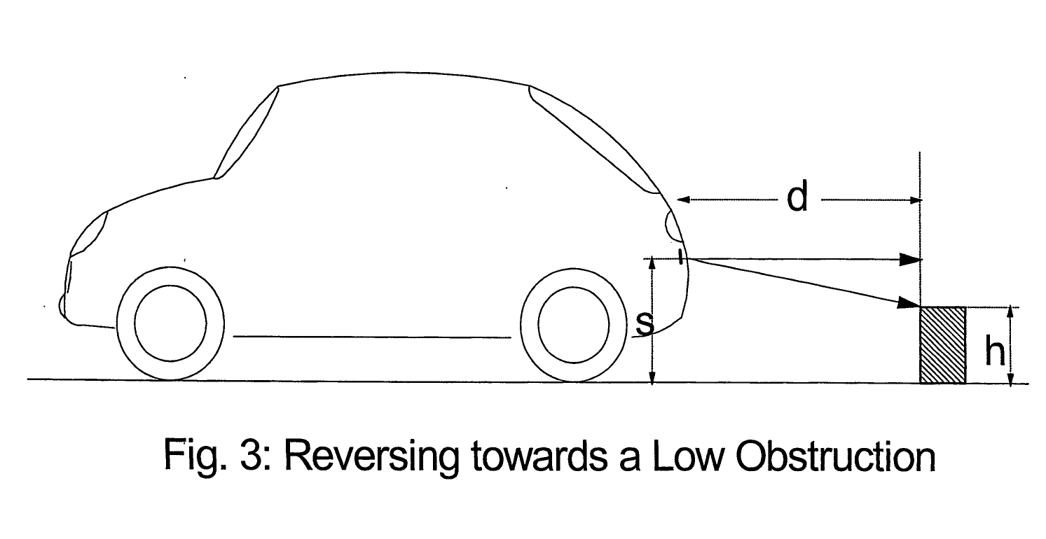

FIG. 3 illustrates the relationship between the sensor output and the distance to a low object;

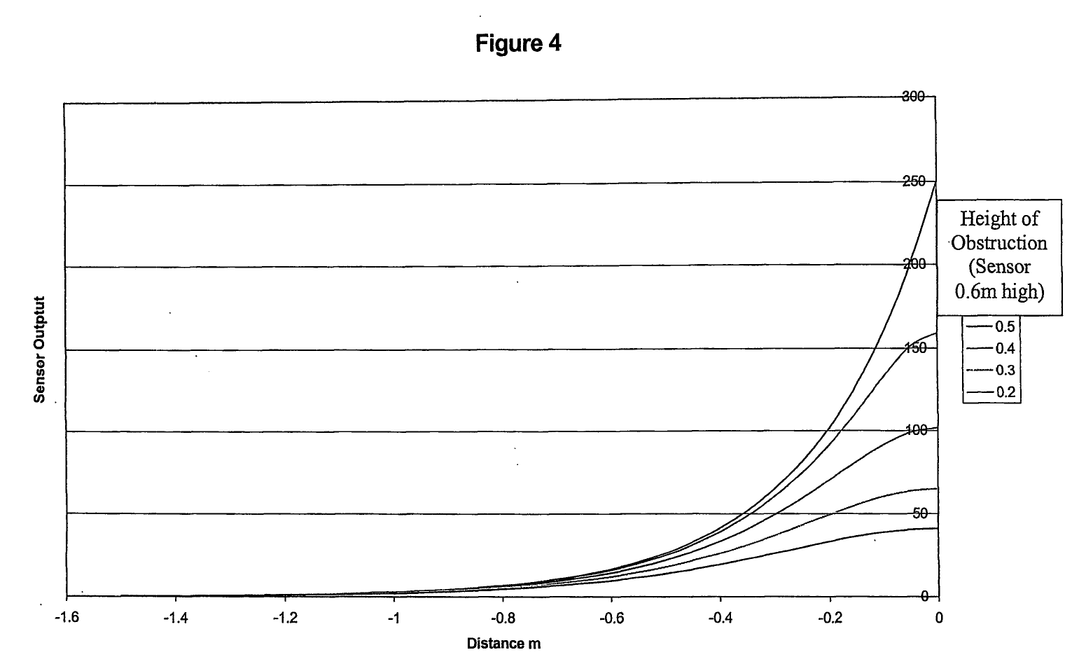

FIG. 4 illustrates the effect of the height of an obstruction on sensor output for a sensor placed at 0.6 m above the ground; and

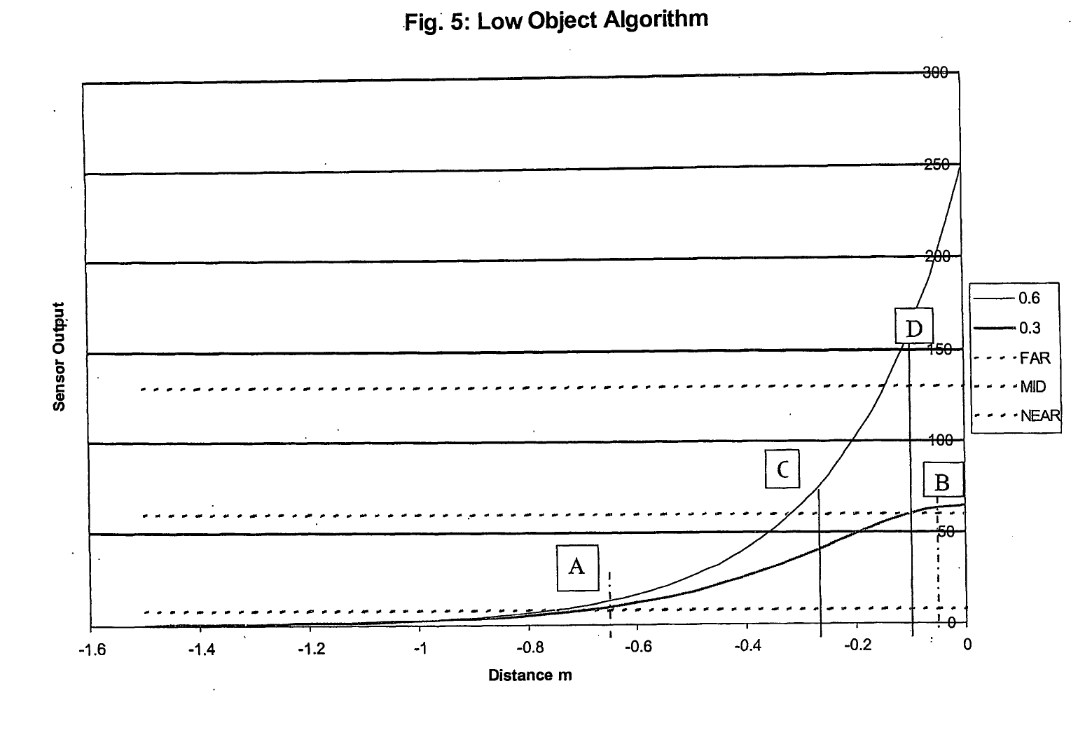

FIG. 5 illustrates a graph comparing how known sensors would detect a low object with the approach according to this first aspect of the present invention; and

FIG. 6 illustrates a basic control and detector circuit of the prior art;

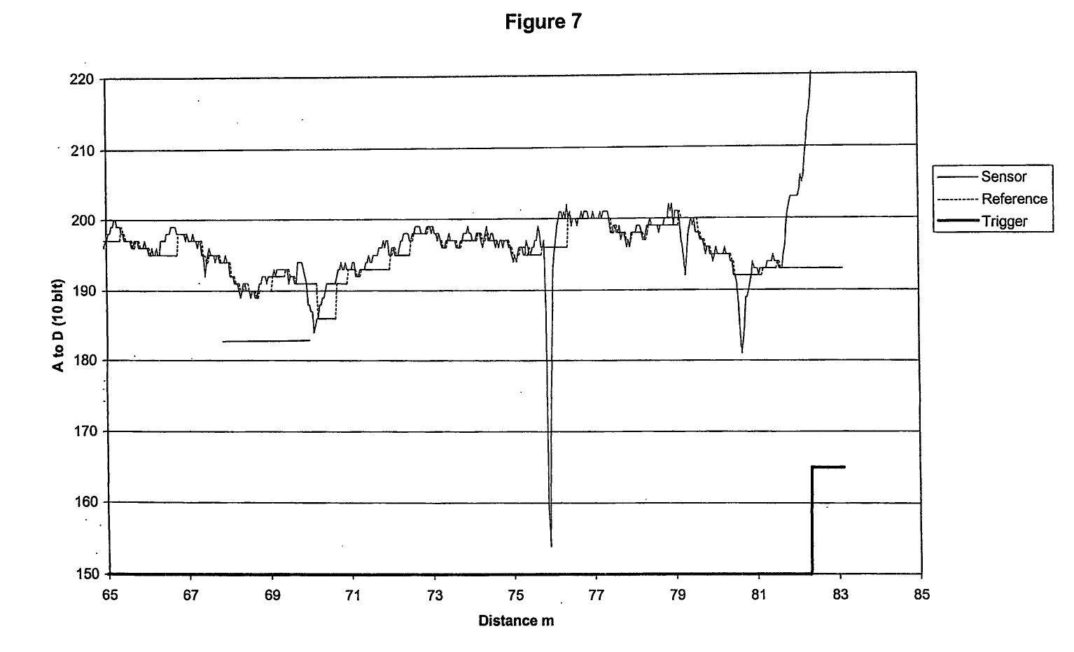

FIG. 7 illustrates a graph of the logged (Ln) output of a capacitive sensor with its controller regulated according to an aspect of the invention.

The relationship between the sensor output and the distance to an obstruction can be approximated by the following equation:
Output=A.e^{Bx}

Where A and B are constants for a particular obstruction/bumper combination and x is the distance to the object.

In practice, the output rises somewhat faster than an exponential, but where the obstruction is more than about 40 cm from the vehicle an exponential is a good approximation.

For simplicity, the output is arbitrarily at zero when the car is a long way from an object, such that x, the distance to that object, has a negative value that increases to zero when the vehicle collides or comes into contact with the object.

The value of A varies considerably for each different obstruction, but will be constant for a particular obstruction. For example, for an object that is difficult to detect, such as a plastic cone, it can be as little as 5% of the value for an object with a strong response such as a parked car, a person or a wall.

The value of B is the distance constant of the system and has approximately the same value for all objects. By making value B the same for all types of obstruction, then the shape of the output curve will be the same, independent of the value of A. Therefore, the point at which the output first registers will be further from the obstruction for larger values of A.

The above phenomena is illustrated in FIG. 2, which compares the output from an object with a strong response, such as a car or person, being the upper graph, with the output from an object with a weaker response, such as a plastic cone, which is of significantly lower magnitude. Comparing these two curves it is also apparent that the output from the object with the stronger response first registers at a distance of approximately −1.5 m, while for the weaker response object, is not apparent until about −0.9 m that an output reading first registers. For the strong response object, the value of A is generally greater than 250, whereas for a poor response object the value of A is generally less than 20.

Therefore, the data stream coming from the sensor is essentially the same for both weak and strong response objects, except in regard to magnitude and the commencement of the output signal. FIG. 2 also shows this principle, with the curve from the object with a poor response cut out and superimposed on the curve for the strong response object.

This principle is also illustrated in Table 1 below.

Table 1 shows the output data stream for incremental movements of 5 cm for various objects having values of A ranging from 20 (poor response object) to 250 (strong response object) where all of the objects are located at the same position. For each object, the highlighted block indicates the data stream that a micro-controller would read as the vehicle approaches each object in turn. From this table it can be seen that the sensor does not detect objects with a weak output response until the vehicle is significantly closer to the object, as compared with objects that have a strong output response. However, once detected, objects with a weaker response do exhibit similar characteristics to those with a stronger response, just with a weaker signal.

TABLE 1

Value of A

| Distance (m) | 20 | 50 | 150 | 250 |
|---|---|---|---|---|
| −1.5 | 0 | 0 | 0 | 0 |
| −1.45 | 0 | 0 | 0 | 0 |
| −1.4 | 0 | 0 | 0 | 0 |
| −1.35 | 0 | 0 | 0 | 1 |
| −1.3 | 0 | 0 | 0 | 1 |
| −1.25 | 0 | 0 | 1 | 1 |
| −1.2 | 0 | 0 | 1 | 1 |
| −1.15 | 0 | 0 | 1 | 1 |
| −1.1 | 0 | 0 | 1 | 2 |
| −1.05 | 0 | 0 | 1 | 2 |
| −1.0 | 0 | 1 | 2 | 3 |
| −0.95 | 0 | 1 | 2 | 3 |
| −0.9 | 0 | 1 | 3 | 4 |
| −0.85 | 0 | 1 | 3 | 5 |
| −0.8 | 1 | 1 | 4 | 7 |
| −0.75 | 1 | 2 | 5 | 9 |
| −0.7 | 1 | 2 | 6 | 11 |
| −0.65 | 1 | 3 | 8 | 13 |
| −0.6 | 1 | 3 | 10 | 17 |
| −0.561 | 2 | 4 | 12 | 20 |
| −0.55 | 2 | 4 | 13 | 21 |
| −0.5 | 2 | 5 | 16 | 26 |
| −0.45 | 3 | 7 | 20 | 33 |
| −0.4 | 3 | 8 | 25 | 41 |
| −0.35 | 4 | 10 | 31 | 52 |
| −0.3 | 5 | 13 | 39 | 65 |
| −0.25 | 6 | 16 | 49 | 81 |
| −0.2 | 8 | 20 | 61 | 102 |
| −0.15 | 10 | 25 | 76 | 127 |

The similarity in the different signals in Table 1 is made more apparent in Table 2 below, which shows the highlighted data in Table 1 side by side.

TABLE 2

| | | | |
|---|---|---|---|
| 0 | 0 | 0 | 0 |
| 0 | 0 | 0 | 0 |
| 1 | 1 | 1 | 1 |
| 1 | 1 | 1 | 1 |
| 1 | 1 | 1 | 1 |
| 1 | 1 | 1 | 1 |
| 1 | 1 | 1 | 1 |
| 2 | 2 | 2 | 2 |
| 2 | 2 | 2 | 2 |
| 2 | 3 | 3 | 3 |
| 3 | 3 | 3 | 3 |
| 3 | 4 | 4 | 4 |
| 4 | 4 | 5 | 5 |
| 5 | 5 | 6 | 7 |
| 6 | 7 | 8 | 9 |
| 8 | 8 | | |

However, as an added complication, where the weak output signal relates to a low object such as a low wall or metal stake, because of the difference in height between the sensor and the obstruction, the effective distance between the sensor and obstruction is greater than the distance measured in the direction of motion of the vehicle. This is illustrated in FIG. 3, where the relationship between the sensor output and the distance to a low object is more appropriately approximated by the following equation:
Output=A. exp (B. sqrt(d²+(s−h)².)

Where d is the distance moved by the vehicle in a direction parallel to the ground, s is the height of the sensor and h is the effective height of the obstruction.

This greater effective distance has the effect that the output from the sensor rises much more slowly than expected for a taller obstruction. To illustrate this, FIG. 4 shows a number of curves for objects of different height, with a-sensor height of 60 cm above the road. From this graph it is apparent that the signal received from low objects, which in practice should rise exponentially at the same rate as higher objects, does not.

Hence, low objects will generally not cause a large enough change in output of the sensor to trigger the appropriate audible warning form their range.

However, although low objects have a low value of A because of their low height, since they nevertheless exhibit a similar sensor data-stream output to objects with a higher value of A, as was illustrated in Tables 1 and 2, this aspect of the invention utilises this relationship to correct the shortcoming for low objects and provide proper warnings.

More specifically, this aspect of the present invention utilises the principle that the data stream coming from the sensor should be essentially the same for both weak and strong response objects, except in regard to magnitude and the commencement of the output signal, in order to compensate for low objects.

In this first aspect of the invention, this principle is utilised by obtaining comparison data being ideal data indicative of an object with a strong response, such as the expected values if the object were at the same height as the sensor. This data may be, for example, actual values of the expected amplitude response over particular incremental distances or a formula representing the data. For instance, amplitude values from the upper graph in FIG. 2 could be retained for 5 cm intervals from zero metres to −1.5 metres.

Where actual ideal data is utilised, this information can be stored in a look-up table in a data storage means such as a memory associated with the control unit. Similarly, where a program calculating the expected shape of the output curve over a change in distance is utilised, the program can be put into a memory associated with the control unit in order to calculate an ideal amplitude value with distance moved.

Preferably the capacitive sensor periodically sends its measurement signals, upon receipt of a triggering pulse from a speed or movement sensor, indicating that the vehicle has moved a particular distance. That is, a speed or movement sensor associated with the vehicle determines when the vehicle moves a particular distance increment, such as 5 cm, and sends the triggering pulse to the capacitive sensor.

The speed or movement sensor can derive the triggering pulse in a number of ways. For example, the speed of the vehicle can be obtained by using a pulse train from a wheel sensor, which gives y transitions per full revolution of a road wheel or a wheel on the output side of the gearbox. Therefore, one pulse per z cm of movement along the ground can be derived. Alternatively, or in addition, messages from a wheel speed sensor such as one associated with an anti-lock brake system can be used. The speed sensor could transmit the messages at short intervals to the controller which would integrate them to calculate the distance travelled.

In operation, once the micro-controller receives an initial signal indicating the detection of a proximate object, the comparison with the ideal data is initiated. The next signal obtained from the capacitive sensor for a particular distance interval is then obtained and also sent to the controller. This next signal is compared with a corresponding value in the ideal data set. To extract the corresponding value from the data set, preferably the amplitude values are stored in a look-up table according to their distance from the initial signal indicating detection of an ideal proximate object. Therefore, by determining an incremental distance moved from the initial point of detection, the corresponding value from the data set may be extracted from the look-up table.

If the comparison shows that the data from the sensor has a lesser amplitude and is therefore a weaker signal, the signal value for the ideal data value in the look-up table is used to boost the output allowing more accurate warning signals to be provided.

In this regard, with reference to Table 2, it can be seen that from the point of detection, the signal amplitude of objects with a strong signal increases at a greater rate than objects with a weaker signal.

More specifically, the comparison is used to determine a moderated output data to send as an activation signal to a warning device. Depending on the value of the activation signal, an appropriate warning signal is created, such as a FAR, M[D or NEAR warning. Therefore, if the corresponding ideal data value in the look-up table is greater than the measured signal value, the moderated output data, which is used for the activation signal, is given the value of the ideal data value from the look-up table.

Alternatively, if the corresponding data value in the look-up table has a value that is equal to or less than the measured value, then this indicates that the detected object is an object with a strong response, and the moderated output data/activation signal is given the value of the measured signal.

From here, for each additional measurement that is obtained, additional comparisons could be made, and the activation signal given the value of the data from the ideal sensor data set as appropriate. Alternatively, where the values from the ideal data set have already been used as the activation signal value, values from the ideal data set could be automatically substituted without further comparisons being made.

It is to be appreciated that while this embodiment of the invention has been described in terms of an ideal data set stored in a look-up table, the general inventive concept is equally applicable to a program stored in memory, whereby, by inputting a particular distance value from the initial point of detection, an ideal amplitude value can be obtained.

Further, instead of directly comparing amplitude values for particular distance intervals, a difference between adjacent measured signals could be compared.

With reference to FIG. 5, a graph is shown which compares how the existing operation of sensors would detect a low object with the approach according to this first aspect of the present invention. The lower graph, being that of a standard sensor operation has distances A and B marked, which would be the points at which a standard sensor would issue FAR and MID warnings. The MID warning would be issued just before the vehicle came into contact with the low object, so no NEAR warning would be issued.

The upper curve illustrates the present invention implemented for the same low object. Through the comparison with an ideal signal, the signal amplitude difference would be noticed earlier (i.e. at a distance of about −0.75 m as compared with −0.68 m), resulting in a FAR warning being first issued earlier than the standard sensor operation as well. The operation of the present invention becomes more marked from hereon, with the MID warning being implemented at point C and a near warning being implemented at point D.

According to another aspect of the invention, a signal matching approach is utilised to extract a signal for an object with a weak response from a noisy data stream. This aspect of the invention may be utilised in conjunction with the aspect just described for improving the sensitivity of capacitive sensors in regard to objects with a weak response, and is based on the same principle.

Considering the data in Table 1, it is apparent that if a little noise were added to the output data stream, as is the case in practice, it would be impossible to tell the signals apart. Hence, the shape of the curve rising out of noise from zero output is the same, independent of the value of A, and this property can also be used to detect obstructions in a noisy data stream.

Preferably, an ideal data set is obtained and stored or a program for calculating the ideal data set is obtained and stored. This data set indicates the expected exponential output that would be obtained from an object with a strong response for particular distance intervals. For instance, amplitude values from the upper graph in FIG. 2 could be retained for 5 cm intervals from zero metres to −1.5 metres.

This ideal data set or calculation program are stored in a memory associated with the controller, which also receives a sequence of measured output signals from the capacitive sensor.

Preferably this sequence of signals is obtained for particular distance intervals (typically 5 cm) and are stored in a buffer associated with the controller, such as a circular buffer. The signals stored in the buffer are compared with the corresponding values in the ideal data set.

If, for example, by determining the error between the actual data and the ideal, the match is equal to or better than a preset threshold, being an acceptable error measure, then an obstruction has been detected, and a warning is triggered. In this way, an object with a weak signal can be more accurately detected and extracted from a noisy data stream.

Considering a specific example, this technique is used to compare the output of the sensor against error data such as a curve stored in memory, where the curve represents an ideal output signal from the sensor which indicates a proximate object. Let us assume that we get one pulse from the wheel speed sensor for every 5 cm of movement along the road. There is a 12 element array in which the values of the sensor for the previous 12 readings have been stored i.e. information about the previous 60 cm of movement.

On receiving each wheel speed pulse, one approach for detecting a signal is as follows:
1. Shift all the data in the array down one place and store the latest data in the location for the most recent (highest no.):
   DistArray[11]→DistArray[10];
   DistArray[10]→DistArray[9];
   . . .
   DistArray[1]→DistArray[0];
   Then
   DistArray[11]:=Latest Sensor Reading.
2. Compare the values in DistArray with the fixed curve (FixedCurve) in memory as follows:
   CorrelationSum: 0;
   For Count:=0 to 11 do
   CorrelationSum:=CorrelationSum+Abs(DistArray[Count]−FixedCurve[Count]);
3. The lower the value of CorrelationSum the closer the match between the sensor data and the fixed curve. A perfect match is 0.
If (CorrelationSum<Threshold) Trigger Audible Warning.
4. Repeat the above for every 5 cm of movement when the vehicle is travelling backwards slowly.

### EXAMPLE

| Distance back | | | |
|---|---|---|---|
| from current | | | Abs(Stored |
| Position | Stored Data | Curve | Data - Curve) |
| 55 cm | 1 | 0 | 1 |
| 50 cm | −1 | 0 | 1 |
| 45 cm | 0 | 1 | 1 |
| 40 cm | 2 | 1 | 1 |
| 35 cm | 1 | 1 | 0 |
| 30 cm | 4 | 1 | 3 |
| 25 cm | 3 | 2 | 1 |
| 20 cm | 4 | 2 | 2 |
| 15 cm | 3 | 3 | 0 |
| 10 cm | 3 | 4 | 1 |
| 05 cm | 6 | 5 | 1 |
| 00 cm | 7 | 6 | 1 |
| CorrelationSum | | | 13 |

The threshold below which an audible warning is triggered depends on road speed, but is typically about 15, so in this case, a trigger would occur.

This technique has been found to produce at least a 20% improvement in range compared with the conventional method based solely on the amplitude of the sensor output. However, it is preferable that this technique is utilised with the conventional amplitude based approach in case the obstruction is moving as well as the vehicle, such as in the case of a child running behind a car.

According to a still further aspect of the invention, the range of the sensor is improved through dynamic adjustment of the micro-controller's reference. In this regard, it is desirable to maintain the accuracy of the micro-controller's reference, as it, as well as the sensor's output, can drift with time and temperature etc. This can be achieved by tracking the sensor output and comparing it with the reference, such as by periodically determining the mean value of the sensor output.

More specifically, in one embodiment a sequence of successive sensor output values are obtained for movement over predetermined incremental distances, such as one value every 5 cm of movement. Some filtering may be applied to the incoming data to remove high frequency noise. This has the effect of smoothing out the effect of bumps and other interferences. Once a particular distance has been travelled, for instance 80 cm, the change of these filtered values is then determined. That is, disregarding spurious measurements, it is determined whether the output of the sensor is increasing relative to the reference or decreasing. If the change over the whole distance is small and the vehicle is moving, then the vehicle can be assumed to be moving over reasonably smooth ground with no obstruction. If this is the case, then the micro-controller's reference is adjusted to account for the movement, such as by taking the latest value of the sensor output. Minor averaging can be made on the sensor output. Otherwise the reference remains unchanged. For example, if the vehicle is moving, and the change in the sensor output is quite large, this is likely to be an indication that an object has been detected, so it would be undesirable to alter the reference. To assess the difference between a small change and a large change, a predetermined threshold value could be used in the comparison. In general though, by examining a sequence of output values, if it is apparent that the output is rising/increasing, then an object has been detected, so no adjustment of the controller reference should take place.

If, however the vehicle is stationary, then the reference will track the sensor output slowly with time. For example, if the output has drifted from 50 to 52 over an update period (e.g. a three second period), at the end of the update period, several output readings are averaged, which shows that the output has drifted upwards. In this situation, the reference is moved towards the sensor output, such as by only one digit from 50 to 51. After a further update period, if there is still an upward drift by the sensor output the reference would be updated to 52. Alternatively, if there were a downward drift, the reference would be decremented by one digit to 50. Therefore, in this way, drift is accommodated while still maintaining sensitivity to anything that will cause a rapid change in sensor output.

By storing the sequence of sensor output signals in a circular buffer, the technique may be continually performed. That is, the first received sensor output signal is discarded, and the latest received sensor output signal put into the buffer before the technique is again performed.

By dynamically updating the micro-controller's reference when it is determined that no obstruction/object exists, a reference accurately reflecting the operating conditions is able to be maintained, resulting in the system becoming more sensitive and its range increased. Further, the dynamic updating technique also allows the amount of false triggering due to bumps and other interferences to be reduced.

FIG. 7 illustrates the result of this dynamic updating technique via a graph of the logged output of a capacitive sensor with its controller regulated. This output signal was obtained when using the sensor in heavy rain with a vehicle backing up towards a hedge, which accounts for the unstable output. The negative spikes are caused by water rolling over the vehicle bumper. The unstable output is mainly because of the heavy rain, but also because of bumps in the road and movement in the vehicle's suspension.

The graph shows the operation of the dynamic updating technique whereby the reference is able to track the changes and follow the sensor. When the car approaches the hedge at the right hand side of the graph, the reference locks and the rising difference between the sensor and reference causes a trigger, which in this instance is a FAR tone, to be generated.

Alterations and additions are possible as will be apparent to the person skilled in the art. For example, rather than triggering the sensor to send signals periodically for a particular distance interval, the distance sensor and the speed sensor could be each triggered to obtain measurement signals for a particular time interval, and the micro-controller could determine the distance travelled for that particular time interval and associate that distance with the amplitude of the signal indicating the distance of the object.

Further, the sensors of the present invention are primarily intended to be mounted on the rear of a vehicle to assist a driver when reversing. However, the sensors are also suitable for front or even side mounting, e.g. for avoiding collisions with objects at low-level which are obscured from view below the bonnet. For example, when a vehicle is manoeuvring, either forwards or backwards, there is a danger that the sides may strike an object if the vehicle is turning at the same time. Therefore, if a vehicle is reversing and tuning, such as into a parking space, the driver will generally be looking towards the rear of the vehicle and his attention may not be on the front of the vehicle which may swing out and collide with an obstruction. A front or side mounted sensor could be provided to detect such objects near the wings particularly in front of the front wheels where most sideways movement occurs.

Such a facility may be provided by a single sensor on the front and sides of the vehicle or two or more separate sensors connected to a single sensing circuit or with their own individual sensing circuits. Where a single sensing circuit is used, the circuit may be arranged such that the two sensors simply act as a single sensor formed in two parts or alternatively, the circuit may use a multiplexer to separately monitor the two sensors sequentially. Similarly, the sensors at the front and rear may be combined and a single sensor used to detect all the sensor plates on the car.

1. A method for detecting an object using a capacitive sensor output signal, comprising:
(a) measuring an output from the capacitive sensor at spaced apart intervals to obtain a sequence of output values;
(b) comparing the sequence of sensor output values with comparison data indicative of an ideal sensor output sequence; and
(c) determining that an object has been detected where a match is obtained between the sequence of output values and the comparison data.

2. The method of claim 1 wherein the sequence of sensor output values are stored in a buffer, and the method further comprises:
(d) measuring a next output value from the capacitive sensor;
(e) deleting a sensor output value according to a FIFO scheme;
(f) adding the next sensor output value to the sequence of sensor output values;
(g) comparing the sequence of sensor output values with the predetermined comparison data;
(h) repeating (d) to (g) until an object is detected.

3. The method of claim 1 wherein said comparing includes obtaining an error value between the sensor output values and the comparison data and determining that a match has been obtained where the error value is less than a threshold value.

4. The method of claim 3 wherein the threshold value corresponds to a predetermined measure of acceptable error between the actual data and the ideal data.

5. The method according to claim 1 wherein the intervals correspond to the sensor moving a predetermined distance.

6. The method of claim 1 wherein the capacitive sensor output is measured at spaced apart intervals using a triggering pulse.

7. The method of claim 6 wherein the triggering pulse is obtained from a speed sensor measuring distance moved by the capacitive sensor.

8. The method of claim 1 wherein the comparison data values relate to an object having a height equal to or greater than a height at which the sensor is positioned, and at intervals in which the sensor moves a predetermined distance.

9. The method of claim 1 wherein the comparison data is stored in a look-up table.

10. The method of claim 1 wherein the comparison data is obtained by calculating an ideal output for a particular change in distance.

11. The method of claim 1, wherein once an object has been detected, the method comprises:
measuring the output from the capacitive sensor at spaced apart intervals;
comparing a measured output value with a corresponding comparison data value indicative of an ideal sensor output to determine if the measured output value differs from the comparison data value; and
determining a moderated output value, such that the moderated output value corresponds to the measured output value except where the comparison shows the measured output value to differ from the corresponding comparison data value, wherein the moderated output value is adjusted to reduce the difference from the comparison data value.

12. The method according to claim 1, wherein the capacitive sensor is used in relation to a vehicle.

13. A vehicle sensor device comprising:
means for measuring an output from the capacitive sensor at spaced apart intervals to obtain a sequence of output values;
data storage means comprising comparison data indicative of an ideal sensor output sequence;
comparator for comparing the sequence of sensor output values with predetermined comparison data indicative of an ideal sensor output sequence; and
means for determining that an object has been detected where a match is obtained between the sequence of output values and the comparison data.

14. The device of claim 13 wherein the data storage means is a look up table.

15. The device of claim 13 further comprising a triggering means for generating a triggering pulse to indicate the spaced apart intervals.

16. The device of claim 15 wherein the triggering means is a speed sensor measuring distance moved by the capacitive sensor.

17. The device of claim 13 further comprising a circular buffer for storing the sequence of measured sensor output values.

18. A method of regulating a controller in a capacitive sensor system, the controller having a controller reference, the method comprising:
measuring output values from the capacitive sensor at spaced apart intervals;
periodically determining whether a comparison value, indicative of the measured output, differs from the controller reference; and
determining whether to update the controller reference based upon the difference between the comparison value and the controller reference.

19. The method of claim 18 further comprising: determining whether the system is in motion; and
(i) where the system is not in motion and the comparison value differs from the controller reference, the controller reference is updated so as to reduce the difference between the comparison value and the controller reference; or
(ii) where the system is in motion:
examining a sequence of output values to determine if an object is detected, and if an object has not been detected and the comparison value differs from the controller reference, updating the controller reference so as to reduce the difference between the comparison value and the controller reference.

20. The method of claim 19 wherein an object is detected when the sequence of output values is increasing.

21. The method of claim 18 wherein the comparison value is calculated by:
filtering spurious values from a sequence of measured sensor output values; and
averaging the sequence of measured sensor output values to obtain the comparison value.

22. The method of claim 21 wherein the controller reference is updated with the last value in the sequence of filtered output values.

23. The method of claim 18 wherein the controller reference is updated by one or more increments or decrements.

24. An apparatus for regulating a controller of a capacitive sensor system comprising:
means for measuring output values from the capacitive sensor at spaced apart intervals;
data storage means for storing a controller reference;
periodically determining whether a comparison value, indicative of the measured output, differs from the controller reference; and
comparator for determining whether a comparison value, indicative of the measured output, differs from the controller reference; and
means for determining whether to update the controller reference based upon the difference between the comparison value and the controller reference.

25. The vehicle sensor device of claim 24 wherein the comparator further comprises:
a filter for filtering spurious values from the measured output values; and
second storage means for storing a sequence of measured output values; and
means for averaging the sequence of measured output values to obtain a comparison value, wherein the comparison value is compared with the controller reference.

26. The device of claim 25 wherein the second storage means is a circular buffer.

27. A method for moderating an output from a capacitive sensor system comprising:
measuring the output from the capacitive sensor at spaced apart intervals;
comparing a measured output value with a corresponding comparison data value indicative of an ideal sensor output to determine if the measured output value differs from the comparison data value; and
determining a moderated output value, such that the moderated output value corresponds to the measured output value except where the comparison shows the measured output value to differ from the corresponding comparison data value, wherein the moderated output value is adjusted to reduce the difference from the comparison data value.

28. The method of claim 27 wherein the moderated output value corresponds to comparison data value when the comparison shows the measured output value to be lower than the comparison data value.

29. The method of claim 27 wherein the output data is only moderated once an object is detected.

30. The method of claim 27 wherein each of the sensor output values measured at spaced apart intervals are sequentially compared with a corresponding comparison data value.

31. The method of claim 27 wherein the comparison data is obtained by calculating an ideal output for a particular change in distance.

32. A vehicle proximity sensor system comprising:
means for measuring an output from the capacitive sensor at spaced apart intervals;
data storage means comprising comparison data indicative of an ideal sensor output;
comparator for comparing a measured output value with a corresponding comparison data value indicative of an ideal sensor output to determine if the measured sensor output value differs from the comparison value by a predetermined amount; and
means for determining a moderated output value, such that the moderated output value corresponds to the measured output value except where the comparison shows the measured output value to differ from the corresponding comparison data value, wherein the moderated output value is adjusted to reduce the difference from the comparison data value.

33. A system as claimed in claim 32 further comprising an output means for outputting the moderated output value to a warning device in order to generate an appropriate warning signal based upon the value of the moderated output.

34-35. (canceled)
